(19) United States
(12) Patent Application Publication
(10) Pub. No.: US 2010/0062608 A1
(43) Pub. Date: Mar. 11, 2010

(54) METHOD FOR SELECTIVE PALSMOCHEMICAL DRY-ETCHING OF PHOSPHOSILICATE GLASS DEPOSITED ON SURFACES OF SILICON WAFERS

(76) Inventors: Volkmar Hopfe, Klelnglesshuebel (DE); Ines Dani, Lichtenau (DE); Elena Lopez, Dresden (DE); Rainer Moeller, Dresden (DE); Moritz Heintze, Ulm (DE)

Correspondence Address: JACOBSON HOLMAN PLLC, 400 SEVENTH STREET N.W., SUITE 600, WASHINGTON, DC, 20004, US

(21) Appl. No.: 12/310,441

(22) PCT Filed: Aug. 29, 2007
(86) PCT No.: PCT/DE2007/001581

§ 371 Date: Nov. 16, 2009

(30) Foreign Application Priority Data
Sep. 1, 2006 (DE) 10 2006 042 329.1

(51) Int. Cl. H01L 21/3065

(52) U.S. Cl. 438/723; 257/E21.218

(57) ABSTRACT

The invention relates to a method for the selective plasmochemical dry-etching of phosphosilicate glass ((SiO₂)ₓP₂O₅)_{y}) formed on surfaces of silicon wafers. In this respect, it is the object of the invention to provide a cost-effective, efficient, selective possibility which at least reduces manufacturing losses and with which phosphosilicate glass can be removed from silicon wafers. A procedure is followed in the invention that crystalline silicon wafers, whose surface is provided with phosphosilicate glass, are etched in a selective plasmochemical process. In this connection, a plasma formed using a plasma source and an etching gas are directed at atmospheric pressure to the phosphosilicate glass which can thus be removed.

The invention relates to a method for the selective plasmochemical dry-etching of phosphosilicate glass ((SiO₂)ₓP₂O₅)_{y}) formed on surfaces of silicon wafers.

In the manufacture of crystalline silicon solar cells, silicon wafers are used which are doped with boron and at whose barrier layer close to the surface an n-doped surface is formed, as an emitter, regionally with diffused phosphorus for the formation of a p-n junction. In this process, a surface layer of phosphosilicate glass (PSG) is formed which subsequently has to be removed again.

In order to remove phosphosilicate glass again and not to remove or otherwise damage the thin film formed with n-doped silicon, or to do so only slightly, this has previously predominantly been done in a wet chemical process in baths containing HF. This is very complex and/or expensive and requires special protective measures, in particular due to the hydrofluoric acid used. In addition, the very thin, and thereby fragile, wafers have to be handled very carefully. Breakage nevertheless frequently occurs, in particular during immersion and removal so that a high loss rate is recorded.

It is known from J. Rentsch et al. from “Industrialisation of Dry Phosphorous Glass Etching and Edge Isolation for Crystalline Silicon Solar Cells”; 20th European Photovoltaic Solar Energy Conference and Exhibition; 6-10 Jun. 2005;

Barcelona, also to carry out a removal by dry etching in a vacuum and using a plasma. However, as is known, this is very complex and/or expensive due to the observation of vacuum conditions in chambers and due to the etching gases used in this process.

In addition, it was found that the selectivity during etching is not sufficient so that the wafers processed in this way have deficits due to an overetching or underetching, that is, an unwanted removal of n-doped silicon or an incomplete removal of phosphosilicate glass.

A method is known from the non-prepublished DE 10 2005 040 596 for the removal of a doped rear side of crystalline Si wafers, wherein etching gas with plasma is directed onto the rear side of a wafer and n-doped silicon is thereby removed there. This should take place under atmospheric pressure conditions. This process is carried out in the manufacture of crystalline structure wafers for solar cells, but only in a subsequent process step after the process in question in accordance with the invention. The process management during etching differs in this respect due to the different materials to be removed. It is thus desired in the invention not to remove any n-doped silicon, but this should be achieved in accordance with this prior art.

Suitable plasma sources which can be operated under atmospheric pressure conditions are known from DE 102 39 875 A1, DE 10 2004 015 216 B4 and the formation of thin films of silicon nitride is known from DE 10 2004 015 217 B4. In these solutions, a plasma source is used to which a gas or gas mixture is supplied for the formation of plasma. Arc plasma sources or microwave plasma sources can be used as plasma sources.

It is therefore the object of the invention to provide a cost-effective, efficient and selective possibility which at least reduces manufacturing losses and with which phosphosilicate glass can be removed from silicon wafers.

In accordance with the invention, this object is solved using a method in accordance with claim 1. Advantageous embodiments and further developments of the invention can be achieved using features designated in the subordinate claims.

A procedure is followed in the invention that crystalline silicon wafers, whose surface is provided with phosphosilicate glass, are etched in a selective plasmochemical process. In this process, a plasma formed using a plasma source and an etching gas are directed at atmospheric pressure to the phosphosilicate glass which can thus be removed. A removal of phosphosilicate glass can thereby take place at the side respectively facing the plasma source and at the outer edges. Atmospheric pressure should be understood in this respect as a pressure range of ±300 Pa around the respective ambient atmospheric pressure.

In this connection, etching gas can be supplied separately and then only reach the phosphosilicate glass to be removed in the region of influence of the plasma before the impact of plasma. Then the splitting into active radicals in the outflowing plasma (remote plasma) takes place.

However, there is also the possibility of using a gas mixture for the plasma formation in which at least one etching gas is contained. In this process, the etching gas preferably reaches the phosphosilicate glass together with further gases or gas mixtures suitable for the formation of plasma. In this case, the active radicals are already produced in the plasma formation zone.

Etching gas can, however, also be supplied both separately and with the plasma, that is, both previously explained options can be combined with one another.

In the method in accordance with the invention, an etching gas can used on its own or also a suitable gas mixture of a plurality of etching gases can be used. CHF₃ and C₂F₆ can advantageously be the etching gas(es).

It has been found that the etching rate and the selectivity during etching can be further improved by the addition of oxygen and/or water vapor. In this respect, an addition of water vapor has an even more advantageous effect.

Apparatus known per se with arc plasma sources or microwave plasma sources can also be used for the method in accordance with the invention. In this respect, options should be available to extract formed reaction products, excess etching gas, reaction products present as waste gas and/or in the form of particles with exhaust gas to be able to supply them to a post-treatment with which pollutants can be converted into non-hazardous components.

In addition, a sealing of the etching reaction region toward the environment should be achieved. This can take place by means of supplied inert flushing gas. In this respect, specific pressures can be observed at regions to be sealed to avoid an escape into the environment of waste gas and any pollutants which may have formed or may still be contained.

Examples for such suitable apparatus are described in DE 102 39 875 A1, DE 10 2004 015 216 B4 or also DE 10 2004 015 217 B4 and would only have to be adapted slightly, if at all, for the carrying out of the method in accordance with the invention. In this connection, it is possible to work in flow so that, in addition to the achievable higher etching selectivity, shorter times for the removal of the phosphosilicate glass layer are required.

Since no further high-temperature step with a longer effect is carried out in the further manufacturing process of silicon solar cells, with which plasma-induced damage to the materials could be healed, the method in accordance with the invention also has an advantageous effect in this sense.

Overetching, with a substantially unfavorable change to the n-doped layer, can be avoided. This also applies to a changed electrical layer resistance which is caused thereby and which would in turn, at finished solar cells, result in a considerably increased electrical resistance at solar cells connected in series.

Dynamic etching rates can be achieved which are substantially above 1 nm*m/s.

As already addressed in the introduction to the description, vacuum processes can also be dispensed with in the overall manufacturing process since the method in accordance with the invention can easily be followed by a process step in accordance with the method described in DE 10 2005 040 596 in which the rear side of the wafer is etched.

Unwanted wet chemistry with the generally known disadvantages can also be dispensed with.

A direct plasma effect and thereby also an impact of ions on the wafer can be avoided.

The invention should be explained by way of example in the following.

There are shown:

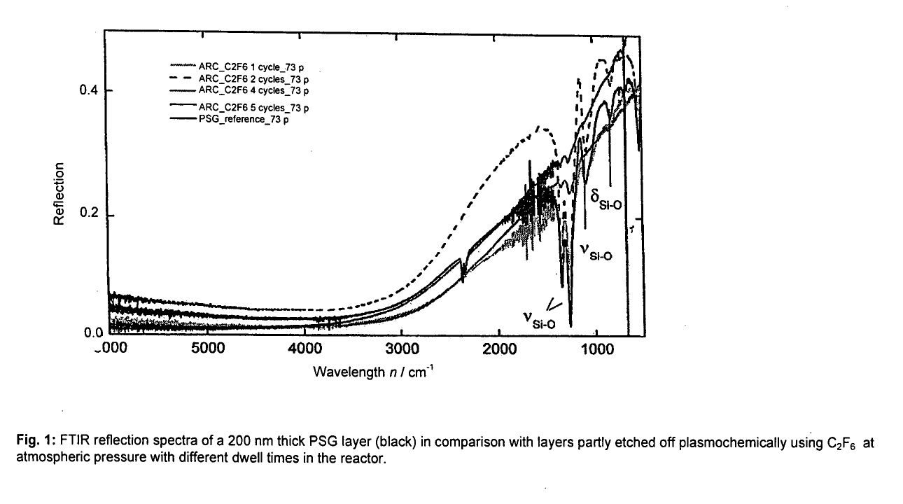

FIG. 1 FTIR reflection spectra of a 200 nm thick phosphosilicate glass layer which has been etched using C_{2F}F₆ in a plasmochemical process at atmospheric pressure and with different dwell times;

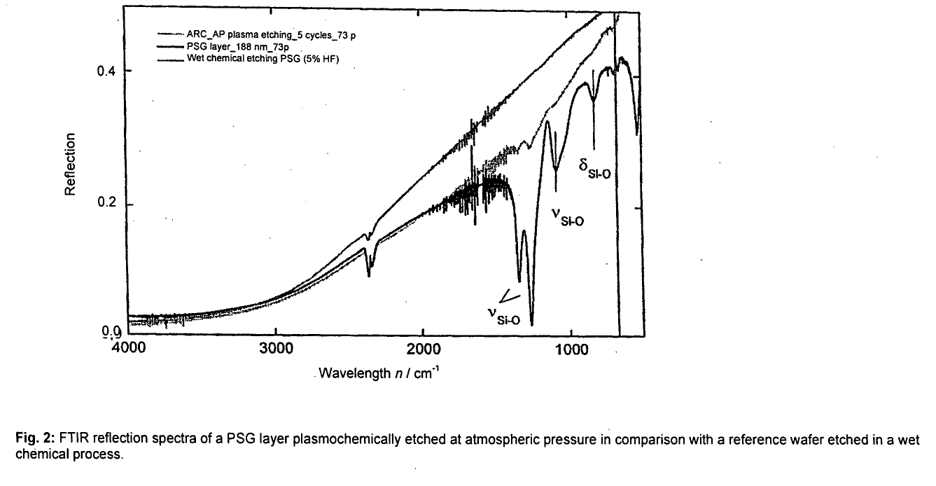

FIG. 2 FTIR reflection spectra from 200 nm thick phosphosilicate glass layers which were etched in a plasmochemical process at atmospheric pressure in comparison with a reference wafer etched in a wet chemical process; and

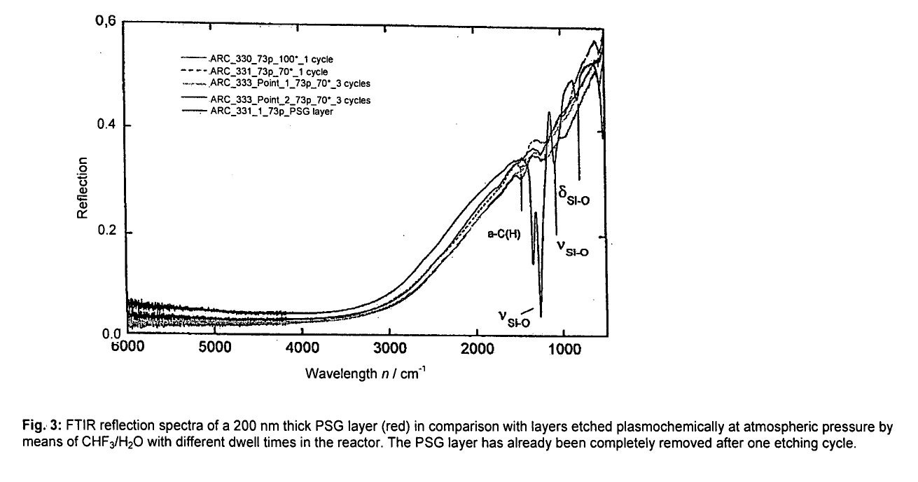

FIG. 3 FTIR reflection spectra of a 200 nm thick phosphosilicate glass layer in comparison with plasmochemical etched at atmospheric pressure by means of CHF₃/H₂O with different dwell times.

An etching gas such as CHF₃ or C₂F₆ or a mixture of an etching gas with oxygen or water vapor is added into a plasma mixture with argon and nitrogen at a ratio of 1:4 after discharge from an arc plasma source. The dynamic etching rate for phosphosilicate glass in this respect is approx. 1 nm*m/s; but the etching rate for silicon is less than 0.1 nm*m/s. A selectivity of greater than 50 can thus reliably be reached.

### EXAMPLE 1

A monocrystalline silicon wafer with dimensions of 125*125 mm which is coated with a layer of phosphosilicate glass of approx. 200 nm thickness and is then, as explained above, etched with a plasma mixture with CHF₃/H₂O. A flow rate for CHF₃ of 1 slm was selected. 3 slm nitrogen was conducted as the carrier gas through an H₂O bubbler. The bubbler temperature was 50° C. The structure and thickness of the phosphosilicate glass layer were determined by means of FTIR reflection spectroscopy at an angle of incidence of 73° and with p polarization. The silicon wafer was subjected to a plurality of etching cycles and was examined again after each cycle by means of

FTIR reflection spectroscopy. It was able to be found that the phosphosilicate glass layer was already completely removed after one cycle (total dwell time per cycle corresponded to 25 s). A dynamic etching rate >1 nm*m/s and a selectivity of >100 results from this.

### EXAMPLE 2

A plasma mixture of argon/oxygen in a ratio of 1:4 and a ratio of plasma gas to remote gas was again selected here. C₂F₆ was used as the etching glass. Five cycles, that is, a total dwell time of 180 s, were required for the complete removal of the phosphosilicate glass layer of 200 nm thickness. An etching rate of 0.1 nm*m/s and a selectivity of 10 could accordingly be achieved.

1. A method for the selective plasmochemical dry etching of phosphosilicate glass formed on surfaces of silicon wafers, wherein a plasma formed by means of a plasma source and an etching gas are directed to the phosphosilicate glass at atmospheric pressure.

2. A method in accordance with claim 1, characterized in that etching gas is supplied to the plasma before the incidence onto the phosphosilicate glass.

3. A method in accordance with claim 1, characterized in that a gas mixture is used for the plasma formation in which at least one etching gas is contained.

4. A method in accordance with claim 1, characterized in that phosphosilicate glass is removed from the front side and from the outer edges of silicon wafers and an n-doped surface layer is exposed.

5. A method in accordance with claim 1, characterized in that CHF₃ and/or C₂F₆ is/are used as the etching gas.

6. A method in accordance with claim 1, characterized in that oxygen and/or water vapor is/are added to the etching gas.

7. A method in accordance with claim 1, characterized in that work is carried out at an ambient pressure in the range ±300 Pa around atmospheric pressure.

8. A method in accordance with claim 1, characterized in that reaction products are extracted as waste gas and/or with waste gas.

9. A method in accordance with claim 1, characterized in that a sealing between an etching reaction region and environmental atmosphere is achieved with a supplied inert flushing gas.

10. A method in accordance with claim 1, characterized in that phosphosilicate glass is removed from silicon wafers in flow.

11. A method in accordance with claim 1, characterized in that plasma is formed using an arc plasma source or a microwave plasma source.
